(19) United States
(12) Patent Application Publication
(10) Pub. No.: US 2009/0283753 A1
(43) Pub. Date: Nov. 19, 2009

(54) Thin film transistor

(75) Inventors: Kai-Li Jiang, Beijing (CN); Qun-Qing Li, Beijing (CN); Shou-Shan Fan, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: Tsinghua University, Beijing City (CN); HON HAI Precision Industry Co., LTD., Tu-Cheng City (TW)

(21) Appl. No.: 12/384,293

(22) Filed: Apr. 2, 2009

(30) Foreign Application Priority Data
May 16, 2008 (CN) 200810067274.7

(51) Int. Cl. H01L 29/66

(52) U.S. Cl. 257/24; 257/E29.168; 977/742; 977/938

(57) ABSTRACT

A thin film transistor includes a source electrode, a drain electrode, a semiconducting layer, and a gate electrode. The drain electrode is spaced from the source electrode. The semiconducting layer is electrically connected to the source electrode and the drain electrode. The semiconductor layer comprises a plurality of carbon nanotubes. A semiconductor layer comprising a plurality of carbon nanotubes electrically connected to the source electrode and the drain electrode, the plurality of carbon nanotubes having almost the same length are substantially parallel to each other and are joined side by side via van der Waals attractive force therebetween. The gate electrode is insulated from the source electrode, the drain electrode, and the semiconducting layer by an insulating layer.

### RELATED APPLICATIONS

This application is related to applications entitled, “METHOD FOR MAKING THIN FILM TRANSISTOR”, filed ______ (Atty. Docket No. US18067); “METHOD FOR MAKING THIN FILM TRANSISTOR”, filed ______ (Atty. Docket No. US17879); “THIN FILM TRANSISTOR”, filed ______ (Atty. Docket No. US18904); “THIN FILM TRANSISTOR”, filed ______ (Atty. Docket No. US19808); “THIN FILM TRANSISTOR PANEL”, filed ______ (Atty. Docket No. US18906); “THIN FILM TRANSISTOR”, filed ______ (Atty. Docket No. US18909); “THIN FILM TRANSISTOR”, filed ______ (Atty. Docket No. US18908); “THIN FILM TRANSISTOR”, filed ______ (Atty. Docket No. US18911); “THIN FILM TRANSISTOR”, filed ______ (Atty. Docket No. US18907); “THIN FILM TRANSISTOR”, filed ______ (Atty. Docket No. US18936); “METHOD FOR MAKING THIN FILM TRANSISTOR”, filed ______ (Atty. Docket No. US19871); and “THIN FILM TRANSISTOR”, filed ______ (Atty. Docket No. US20078). The disclosures of the above-identified applications are incorporated herein by reference.

### BACKGROUND

1. Technical Field

The present invention relates to thin film transistors and, particularly, to a carbon nanotube based thin film transistor.

2. Discussion of Related Art

A typical thin film transistor (TFT) is made of a substrate, a gate electrode, an insulation layer, a drain electrode, a source electrode, and a semiconductor layer. The thin film transistor performs as a switch by modulating an amount of carriers accumulated at an interface between the insulation layer and the semiconducting layer.

Generally, the material of the semiconductor layer is amorphous silicone (a-Si), poly-silicone (p-Si), or organic semiconducting material. The carrier mobility of an a-Si TFT is lower than a p-Si TFT. However, the method for making the p-Si TFT is complicated and has a high cost. The organic TFT has the virtue of being flexible but has low carrier mobility.

Carbon nanotubes (CNTs) are a novel carbonaceous material and have received a great deal of interest since the early 1990s. Carbon nanotubes have interesting and potentially useful heat conducting, electrical conducting, and mechanical properties. Further, there are two kinds of carbon nanotubes: metallic carbon nanotubes and semiconducting carbon nanotubes determined by the arrangement of the carbon atoms therein. The carrier mobility of semiconducting carbon nanotubes along a length direction can reach about 1000 to 1500 cm²V⁻¹s⁻¹. Thus, a TFT employing a semiconductor layer adopting carbon nanotubes has been produced.

However, the carbon nanotubes in the conventional TFT are distributed as a disordered carbon nanotube layer or perpendicular to the substrate as a carbon nanotube array. In the disordered carbon nanotube layer, due to disordered arrangement of the carbon nanotubes, the paths for carriers to travel are relatively long resulting in low carrier mobility. Further, the disordered carbon nanotube layer is formed by printing a mixture of a solvent with the carbon nanotubes dispersed therein on the substrate. The carbon nanotubes in the disordered carbon nanotube layer are joined or combined to each other by an adhesive agent. Thus, the disordered carbon nanotube layer has a hardened structure and is not suitable for being used in a flexible TFT.

In the carbon nanotube array, the carbon nanotubes are perpendicular to the substrate. However, although the carbon nanotubes have good carrier mobility along the length direction, the carrier mobility of the carbon nanotube array along a direction parallel to the substrate is relatively low.

In sum, the two kinds of carbon nanotube structure employed in the conventional TFT have low carrier mobility and poor flexibility.

What is needed, therefore, is a TFT in which the above problems are eliminated or at least alleviated.

### BRIEF DESCRIPTION OF THE DRAWINGS

Many aspects of the present TFT can be better understood with references to the following drawings. The components in the drawings are not necessarily drawn to scale, the emphasis instead being placed upon clearly illustrating the principles of the present TFT.

FIG. 1 is a cross sectional view of a TFT in accordance with a first embodiment.

FIG. 2 shows a Scanning Electron Microscope (SEM) image of a carbon nanotube film segment used in the TFT of FIG. 1.

FIG. 3 is a schematic view of the TFT of FIG. 1 connected to a circuit.

FIG. 4 is a cross sectional view of a TFT in accordance with a second embodiment.

Corresponding reference characters indicate corresponding parts throughout the several views. The exemplifications set out herein illustrate at least one embodiment of the present TFT, in at least one form, and such exemplifications are not to be construed as limiting the scope of the invention in any manner.

### DETAILED DESCRIPTION OF EXEMPLARY EMBODIMENTS

References will now be made to the drawings to describe, in detail, embodiments of the present TFT.

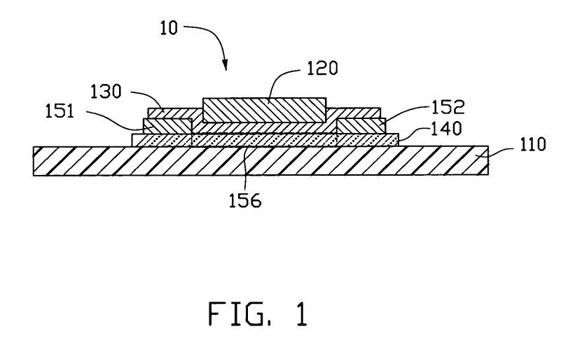

Referring to FIG. 1, a TFT 10 is provided in a first embodiment, and has a top gate structure. The TFT 10 includes a semiconductor layer 140, a source electrode 151, a drain electrode 152, an insulating layer 130, and a gate electrode 120. The TFT 10 is located on an insulating substrate 110.

The insulating substrate 110 is provided for supporting the TFT 10. The insulating substrate 110 can be a substrate employed in a printed circuit board (PCB). Alternatively, the insulating substrate 10 can be made of rigid materials (e.g., p-type or n-type silicon, silicon with a silicon dioxide layer formed thereon, crystal, crystal with an oxide layer formed thereon), or flexible materials (e.g., plastic or resin). In the present embodiment, the material of the insulating substrate is glass. The shape and the size of the insulating substrate 110 are arbitrary. A plurality of TFTs 10 can be assembled on a single insulating substrate 110 in a pattern according to design needs.

The semiconducting layer 140 is located on the insulating substrate 110. The source electrode 151 is spaced from the drain electrode 152. Both the source electrode 151 and the drain electrode 152 are electrically connected to the semiconducting layer 140. The insulating layer 130 is located between the semiconducting layer 140 and the gate electrode 120. The insulating layer 130 is located on a portion of the semiconducting layer 140, or covers the semiconducting layer 140, the source electrode 151, and the drain electrode 152. The gate electrode 120 is located on the insulating layer 130. The insulating layer 130 is configured to provide the electrical insulation between the semiconducting layer 140, the source electrode 151, and the drain electrode 152. A channel 156 is formed and located at portion of the semiconducting layer 140 between the source electrode 151 and the drain electrode 152. The channel 156 can be part of the semiconducting layer 140.

The source electrode 151 and the drain electrode 152 can be located on the semiconducting layer 140 or on the insulating substrate 110. More specifically, the source electrode 151 and the drain electrode 152 can be located on a top surface of the semiconducting layer 140, and located at the same side of the semiconducting layer 140 as the gate electrode 120. In other embodiments, the source electrode 151 and the drain, electrode 152 can be located on the insulating substrate 110 and covered by the semiconducting layer 140 (not shown). The source electrode 151 and the drain electrode 152 may be located on different sides of the semiconducting layer 140 from the gate electrode 120. In other embodiments, the source electrode 151 and the drain electrode 152 can be formed on the insulating substrate 110, and coplanar with the semiconducting layer 140.

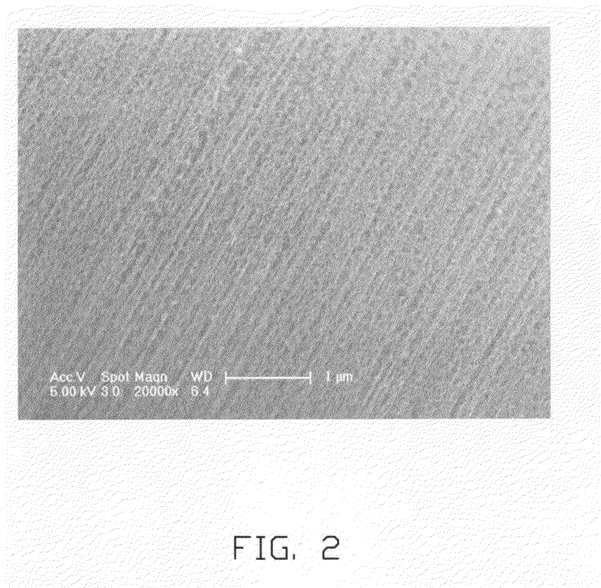

The semiconducting layer 140 includes a plurality of carbon nanotubes. Opposite ends of at least some of the carbon nanotubes are electrically connected to the source electrode 151 and the drain electrode 152. Referring to FIG. 2, the plurality of carbon nanotubes can be arranged along a preferred orientation extending from the source electrode 151 to the drain electrode 152. The plurality of carbon nanotubes are substantially parallel to each other, generally equal in length, and are combined side by side via van der Waals attractive force therebetween. A length of the semiconductor layer along a direction extending from the source electrode to the drain electrode is equal to the length of the carbon nanotubes. The plurality of carbon nanotubes is parallel to the surface of the semiconductor layer 140. The carbon nanotubes are semiconducting carbon nanotubes. The carbon nanotubes can be selected from a group consisting of the single-walled carbon nanotubes, double-walled carbon nanotubes, and combinations thereof. The diameter of the single-walled carbon nanotube is in the range from about 0.5 nanometers to about 50 nanometers. The diameter of the double-walled carbon nanotube is in the range from about 1 nanometer to about 50 nanometers. In the present embodiment, the diameter of the semiconducting carbon nanotube is less than about 10 nanometers. The length of the carbon nanotubes ranges from about 1 micrometer to about 10 millimeters.

The semiconductor layer 140 can include at least one carbon nanotube film segment. The carbon nanotubes in the carbon nanotube film segment can be substantially parallel to each other, have an almost equal length and be combined side by side via van der Waals attractive therebetween. The length of the film segment is equal to the length of the carbon nanotubes. Such that at least one carbon nanotube will span the entire length of the carbon nanotube film segment. The length of the carbon nanotube film segment is only limited by the length of the carbon nanotubes. The semiconductor layer can further comprise at least two stacked carbon nanotube film segments. Adjacent carbon nanotube film segments are combined together by van der Waals attractive therebetween. An angle between the aligned directions of the carbon nanotubes in adjacent carbon nanotube film segments ranges from 0 degrees to 90 degrees inclusive.

A length of the semiconducting layer 140 can be in a range from about 1 micrometer to about 100 micrometers. A width of the semiconducting layer 140 can be in a range from about 1 micrometer to about 1 millimeter. A thickness of the semiconducting layer 140 can be in a range from about 0.5 nanometers to about 100 micrometers. A length of the channel 156 can be in a range from about 1 micrometer to about 100 micrometers. A width of the channel 156 (i.e., a distance from the source electrode to the drain electrode) can be in a range from about 1 micrometer to about 1 millimeter.

In the present embodiment, the semiconductor layer 140 includes a carbon nanotube film segment. The carbon nanotube film segment includes a plurality of carbon nanotubes. The carbon nanotubes are parallel to each other, are generally equal in length, and combined side by side via van der Waals attractive force therebetween. The carbon nanotubes are all arranged along a direction extending from the source electrode 151 to the drain electrode 152. Two ends of the carbon nanotubes are electrically connected to the source electrode 151 to the drain electrode 152. The length of the film segment is equal to the length of the carbon nanotubes. The length of the semiconducting layer 140 is about 50 micrometers. The width of the semiconducting layer is about 300 micrometers. The thickness of the semiconducting layer 140 is about 25 nanometers. The length of the channel 156 is about 40 micrometers, and the width of the channel 156 is about 300 micrometers. The channel 156 is part of the semiconductor layer 140 and is made of carbon nanotubes. In the present embodiment, the channel 156 includes a carbon nanotube film segment.

The source electrode 151, the drain electrode 152, and/or the gate electrode 120 are made of conductive material. In the present embodiment, the source electrode 151, the drain electrode 152, and the gate electrode 120 are conductive films. A thickness of the conductive film can be in a range from about 0.5 nanometers to about 100 micrometers. The material of the source electrode 151, the drain electrode 152, and the gate electrode 120 comprises a material selected from the group consisting of metal, alloy, indium tin oxide (ITO), antimony tin oxide (ATO), silver paste, conductive polymer, metallic carbon nanotubes and combination thereof. The metal or alloy can be selected from the group consisting of aluminum (Al), copper (Cu), tungsten (W), molybdenum (Mo), gold (Au), titanium (Ti), neodymium (Nd), palladium (Pd), cesium (Cs), and combinations of the above-mentioned metal. In the present embodiment, the source electrode 151, the drain electrode 152, and the gate electrode 120 are Pd films. A thickness of the Pd film is about 5 nanometers. The Pd films have good wettability.

The material of the insulating layer 130 can be a rigid material such as silicon nitride (Si₃N₄), silicon dioxide (SiO₂), or a flexible material such as polyethylene terephthalate (PET), benzocyclobutenes (BCB), polyester or acrylic resins. A thickness of the insulating layer 130 can be in a range from about 5 nanometers to about 100 microns. In the present embodiment, the insulating layer 130 is made from Si₃N₄.

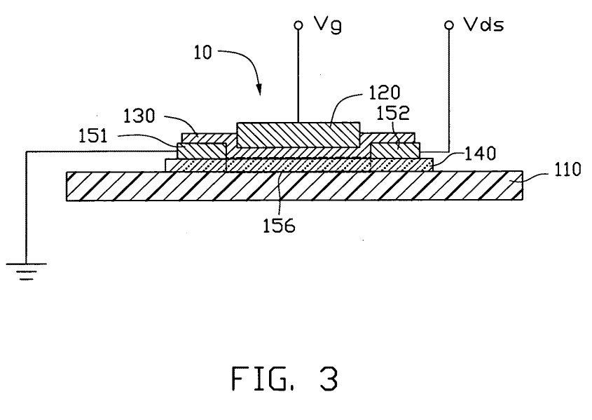

Referring to FIG. 3, in use, the source electrode 151 is grounded. A voltage Vds is applied to the drain electrode 152. Another voltage Vg is applied on the gate electrode 120. The voltage Vg forms an electric field in the channel 156 of the semiconducting layer 140. Accordingly, carriers exist in the channel near the gate electrode 120. As the Vg increasing, a current is generated and flows through the channel 156. Thus, the source electrode 151 and the drain electrode 152 are electrically connected. The carrier mobility of the semiconducting carbon nanotubes along the length direction thereof is relatively high, and the carbon nanotubes of the carbon nanotube film segment are aligned substantially from the source electrode 151 to the drain electrode 152. Therefore, the paths for the carriers to travel in the semiconducting layer 140 are short, causing high carrier mobility. In the present embodiment, the carrier mobility of the TFT 10 is higher than about 10 cm²/V⁻¹s⁻¹ (e.g., 10 to 1500 cm²/V⁻¹s⁻¹), and the on/off current ratio of the TFT 10 is in a range from about 1.0×10² to about 1.0×10⁶.

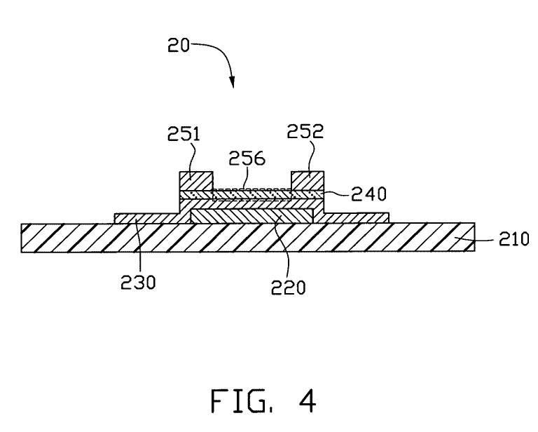

Referring to FIG. 4, a TFT 20 is provided in a second embodiment and has a bottom gate structure. The TFT 20 includes a gate electrode 220, an insulating layer 230, a semiconducting layer 240, a source electrode 251, and a drain electrode 252. The TFT 20 is located on an insulating substrate 210.

The composition, features and functions of the TFT 20 in the second embodiment are similar to the TFT 10 in the first embodiment. The difference is that, the gate electrode 220 of the second embodiment is located on the insulating substrate 210. The insulating layer 230 covers the gate electrode 220. The semiconducting layer 240 is located on the insulating layer 230, and insulated from the gate electrode 220 by the insulating layer 230. The source electrode 251 and the drain electrode 252 are spaced apart from each other and electrically connected to the semiconducting layer 240. The source electrode 251, and the drain electrode 252 are insulated from the gate electrode 220 by the insulating layer 230. A channel 256 is formed in the semiconducting layer 240 in a region between the source electrode 251 and the drain electrode 252.

The source electrode 251 and the drain electrode 252 can be located on the semiconducting layer 240 or on the insulating layer 230. More specifically, the source electrode 251 and the drain electrode 252 can be located on a top surface of the semiconducting layer 240, and at the same side of the semiconducting layer 240 with the gate electrode 220. In other embodiments, the source electrode 251 and the drain electrode 252 can be located on the insulating layer 230 and covered by the semiconducting layer 240. The source electrode 251 and the drain electrode 252 are at a different side of the semiconducting layer 240 from the gate electrode 220. In other embodiments, the source electrode 251 and the drain electrode 252 can be formed on the insulating layer 230, and coplanar with the semiconducting layer 240. The semiconducting layer 240 includes a plurality of carbon nanotubes.

The TFTs provided in the present embodiments have at least the following superior properties: firstly, the carbon nanotubes in the semiconducting layer are arranged along the preferred direction extending from the source electrode to the drain electrode. Thus, the paths for the carriers to travel in the semiconducting layer 140 are minimum, and the carrier mobility of the TFT is relatively high. Secondly, the carbon nanotubes are tough and flexible. Thus, TFTs using metallic carbon nanotubes as electrodes can be durable and flexible. Thirdly, the carbon nanotubes are durable at high temperatures. Therefore, the TFT using carbon nanotubes as the semiconducting layer can be used in high temperature. Fourthly, the thermal conductivity of the carbon nanotubes is relatively high, and the carbon nanotubes in the semiconducting layer are aligned along a same direction. Thus, in use, heat produced by the TFT can be rapidly spread out and easily dissipated.

It is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A thin film transistor comprising:
a source electrode;
a drain electrode spaced from the source electrode;
a semiconductor layer comprising a plurality of carbon nanotubes connected to the source electrode and the drain electrode, the plurality of carbon nanotubes having almost the same length are substantially parallel to each other and are joined side by side via van der Waals attractive force therebetween; and
a gate electrode insulated from the source electrode, the drain electrode, and the semiconducting layer by an insulating layer.

2. The thin film transistor of claim 1, wherein the plurality of carbon nanotubes are parallel to a surface of the semiconductor layer.

3. The thin film transistor of claim 1, wherein the plurality of carbon nanotubes extend from the source electrode to the drain electrode.

4. The thin film transistor of claim 1, wherein the carbon nanotubes are semiconducting carbon nanotubes.

5. The thin film transistor of claim 1, wherein the carbon nanotubes are selected from a group consisting of the single-walled carbon nanotubes, double-walled carbon nanotubes, and combinations thereof.

6. The thin film transistor of claim 1, wherein a diameter of each of the carbon nanotubes is less than 10 nanometers.

7. The thin film transistor of claim 1, wherein the length of the semiconductor layer along a direction extending from the source electrode to the drain electrode is equal to the length of the carbon nanotubes.

8. The thin film transistor of claim 1, wherein the semiconductor layer comprises at least one carbon nanotube film segment, and the carbon nanotube film segment comprises of the plurality of carbon nanotubes.

9. The thin film transistor of claim 8, wherein the semiconductor layer comprises two or more carbon nanotube film segments stacked successively, adjacent two carbon nanotube film segments are attracted by van der Waals attractive force therebetween, and the aligned directions of the carbon nanotubes in the two adjacent carbon nanotube film segments are set at an angle ranging from more than or equal to 0 degrees to less than or equal to 90 degrees.

10. The thin film transistor of claim 1, wherein the insulating layer is located between the semiconductor layer and the gate electrode, and the insulating layer comprises of a material that is selected from the group consisting of silicon nitride, silicon dioxide, benzocyclobutene, polyester and acrylic resin.

11. The thin film transistor of claim 1, wherein the source electrode, the drain electrode, and the gate electrode comprise of at least one material that is selected from the group consisting of metal, alloy, indium tin oxide, antimony tin oxide, silver paste, conductive polymer, metallic carbon nanotube and combinations thereof.

12. The thin film transistor of claim 11, wherein the metal is selected from the group consisting of aluminum, copper, tungsten, molybdenum, gold, titanium, neodymium, palladium, cesium, and alloy thereof.

13. The thin film transistor of claim 1, wherein the semiconductor layer is located on an insulating substrate, the source electrode and the drain electrode are located on the semiconductor layer, the insulating layer is located on the semiconducting layer, and the gate electrode is located on the insulating layer.

14. The thin film transistor of claim 1, wherein the gate electrode is located on an insulating substrate, the insulating layer is located on the gate electrode, the semiconducting layer is located on the insulating layer, the source electrode and the drain electrode are located on the semiconducting layer.

15. The thin film transistor of claim 1, wherein the carrier mobility of the thin film transistor ranges from about 10 to about 1500 cm²/V⁻¹s⁻¹, and an on/off current ratio thereof ranges from about 1.0×10² to about 1.0×10⁶.

16. The thin film transistor of claim 1, further comprising a channel located at potion of the semiconductor layer between the source electrode and the drain electrode.

17. The thin film transistor of claim 16, wherein the length of the channel is in a range from about 1 micrometer to about 100 micrometers, the width of the channel is in a range from about 1 micrometer to about 1 millimeter, the thickness of the channel is in a range from about 0.5 nanometers to about 100 micrometers.

18. The thin film transistor of claim 16, wherein the channel comprises of the carbon nanotubes.

19. The thin film transistor of claim 16, wherein the channel comprises at least one carbon nanotube film segment.

20. A thin film transistor comprising:
a source electrode;
a drain electrode spaced from the source electrode;
a semiconducting layer connected to the source electrode and the drain electrode, wherein the semiconducting layer comprises a plurality of carbon nanotubes, and the two ends of each carbon nanotube are electrically connected to the source electrode and the drain electrode respectively; and
a gate electrode insulated from the source electrode, the drain electrode, and the semiconducting layer by an insulating layer.
